(19) United States
(12) Patent Application Publication
(10) Pub. No.: US 2024/0147865 A1
(43) Pub. Date: May 2, 2024

(54) PIEZOELECTRIC LINEAR MOTOR AND ELECTRONIC DEVICE

(71) Applicant: AAC Microtech (Changzhou) Co., Ltd., Changzhou (CN)

(72) Inventors: Wen Zhong, Changzhou (CN); Zhuofan Zhou, Changzhou (CN); Wenbiao Xu, Changzhou (CN)

(21) Appl. No.: 18/325,950

(22) Filed: May 30, 2023

Related U.S. Application Data
(63) Continuation of application No. PCT/CN2022/132242, filed on Nov. 16, 2022.

(30) Foreign Application Priority Data
Nov. 2, 2022 (CN) 202211362978.3

(51) Int. Cl. H10N 30/20; H02N 2/04; H10N 30/87; H10N 30/88

(52) U.S. Cl. CPC H10N 30/2046; H02N 2/04; H10N 30/871; H10N 30/88

(57) ABSTRACT

A piezoelectric linear motor and an electronic device, including a piezoelectric actuator and an elastic structure fixed to two opposite sides of the actuator. The piezoelectric actuator extends/retracts to drive the elastic structure to move when a voltage is applied. The elastic structure includes sets of elastic connecting portions fixed to end portions of the piezoelectric actuator, each set includes two connecting legs fixed to two opposite sides of the piezoelectric actuator, each connecting leg extends toward an outer side of the piezoelectric actuator, and connecting legs located at a same side of the piezoelectric actuator extend away from each other, and an angle is formed between each of the connecting legs and a plane where the piezoelectric actuator is located. The connecting legs have better flexibility, the elastic structure has stronger deformation capability, a haptic feedback response speed is increased and thickness of the piezoelectric linear motor is reduced.

### TECHNICAL FIELD

The present disclosure relates to the technical field of haptic feedback, and in particular, to a piezoelectric linear motor and an electronic device.

### BACKGROUND

At present, haptic feedback can be realized by using an inverse piezoelectric effect of a piezoelectric material. For example, when a voltage is applied to the piezoelectric material, the piezoelectric material deforms, and the deformation is transmitted to human fingers to realize haptic feedback.

In the related art, an electronic device with a haptic feedback function includes a piezoelectric actuator made of a piezoelectric material and an elastic structure fixed to the piezoelectric actuator. The elastic structure includes two elastic pieces arranged on upper and lower side surfaces of the piezoelectric actuator. Two ends of each of the elastic pieces are respectively fixed to two ends of the piezoelectric actuator, and there is a movable space between the middle of the elastic piece and the piezoelectric actuator. The elastic piece can be driven by the piezoelectric actuator to move to generate haptic feedback. However, due to the inflexible structure of the elastic piece, an elastic force is small, and the deformation capability of the elastic structure is poor, resulting in a slow haptic feedback response speed and low feedback intensity of the electronic device, which is not easily perceived.

Therefore, there is a need to provide a new piezoelectric linear motor.

### SUMMARY

In an aspect, the present disclosure provides a piezoelectric linear motor, including: a piezoelectric actuator; and an elastic structure fixed to two opposite sides of the piezoelectric actuator along a first direction, the first direction being perpendicular to a plane where a telescopic direction of the piezoelectric actuator is located. The piezoelectric actuator is configured to extend and retract to drive the elastic structure to move in the first direction when a voltage is applied. The elastic structure includes at least two sets of elastic connecting portions fixed to end portions of the piezoelectric actuator along the telescopic direction, each set of the at least two sets of elastic connecting portions includes two connecting legs respectively fixed to two opposite sides of the piezoelectric actuator along the first direction, each of the connecting legs extends toward an outer side of the piezoelectric actuator, and the connecting legs located at a same side of the piezoelectric actuator along the first direction extend in a direction away from each other, and an angle is formed between each of the connecting legs and a plane where the piezoelectric actuator is located.

As an improvement, the angle formed between the connecting leg and the plane where the piezoelectric actuator is located is smaller than 45°.

As an improvement, each set of the at least two sets of elastic connecting portions further includes a connecting assembly fixed to the piezoelectric actuator, and each of the connecting legs is fixed to the piezoelectric actuator through the connecting assembly; each of the connecting legs includes a cantilever portion fixed to the connecting assembly and a first connecting portion fixed to an end of the cantilever portion away from the connecting assembly, and the angle is formed between the cantilever portion and the plane where the piezoelectric actuator is located.

As an improvement, the connecting assembly at least includes a first fixation portions respectively connecting the cantilever portion of each of the connecting legs and the piezoelectric actuator, the first fixation portion is in a shape of a flat plate, the first fixation portions connecting a same set of the at least two sets of elastic connecting portions are fixed to two opposite surfaces of the piezoelectric actuator along the first direction, respectively.

As an improvement, the cantilever portion and the first fixation portion, and the first connecting portion and the cantilever portion are connected by bending or smooth transition.

As an improvement, a thicknesses of a junction between the cantilever portion and the first fixation portion is smaller than a thickness of the cantilever portion, and a thickness of a junction between the first connecting portion and the cantilever portion is smaller than the thickness of the cantilever portion.

As an improvement, the first fixation portions connecting the connecting legs of a same set of the elastic connecting portions are formed into one piece; or the connecting assembly further includes a second fixation portion fixed to an outer side wall of the piezoelectric actuator, and the first fixation portions connecting the connecting legs of a same set of the elastic connecting portions are connected to each other through the second fixation portion.

As an improvement, the connecting assembly connecting a same set of the elastic connecting portions further includes a third fixation portion extending from one of the first fixation portions along the first direction and fixed to an outer side wall of the piezoelectric actuator, and the cantilever portions of the connecting legs located at a side of the piezoelectric actuator along the first direction are each fixed to the piezoelectric actuator through the first fixation portion; and the cantilever portions of the connecting legs located at another side of the piezoelectric actuator along the first direction are each connected to the third fixation portion.

As an improvement, the connecting legs located at a same side of the piezoelectric actuator along the first direction are formed into one piece.

As an improvement, the connecting assembly further includes a second connecting portion connecting the first fixation portions located on a same side of the piezoelectric actuator along the first direction, the second connecting portion being arranged apart from the piezoelectric actuator along the first direction.

As an improvement, the piezoelectric linear motor further includes two pressing members fixed to the piezoelectric actuator and located at two opposites sides of the piezoelectric actuator along the telescopic direction, the connecting assembly connects each of the two pressing members and the cantilever portion, and the two pressing members jointly form a pre-tightening force that compresses the piezoelectric actuator along the telescopic direction of the piezoelectric actuator.

As an improvement, the elastic structure further includes a reinforcing member connecting the connecting legs located at a same side of the piezoelectric actuator along the first direction, the reinforcing member and the connecting legs located at the same side of the piezoelectric actuator are formed into one piece, or the reinforcing member is connected to each of the connecting legs located at the same side of the piezoelectric actuator through a fixation member.

As an improvement, the reinforcing member includes a flat portion parallel to the plane where the piezoelectric actuator is located, and a bending portion extending from each of two ends of flat portion in a direction perpendicular to the first direction and connected to the first connecting portion, and the fixation member is arranged between the bending portion and the first connecting portion or the bending portion and the first connecting portion are formed into one piece.

In an aspect, the present disclosure provides an electronic device, including a first substrate, a second substrate, and at least one piezoelectric linear connected to the first substrate and the second substrate. Each of the at least one piezoelectric linear motor includes: a piezoelectric actuator; and an elastic structure fixed to two opposite sides of the piezoelectric actuator along a first direction, the first direction being perpendicular to a plane where a telescopic direction of the piezoelectric actuator is located. The piezoelectric actuator is configured to extend and retract to drive the elastic structure to move in the first direction when a voltage is applied. The elastic structure includes at least two sets of elastic connecting portions fixed to end portions of the piezoelectric actuator along the telescopic direction, each set of the at least two sets of elastic connecting portions includes two connecting legs respectively fixed to two opposite sides of the piezoelectric actuator along the first direction, each of the connecting legs extends toward an outer side of the piezoelectric actuator, and the connecting legs located at a same side of the piezoelectric actuator along the first direction extend in a direction away from each other, and an angle is formed between each of the connecting legs and a plane where the piezoelectric actuator is located. The piezoelectric linear motor is configured to drive at least tone of the first substrate or the second substrate to move along the first direction when a voltage is applied.

### BRIEF DESCRIPTION OF DRAWINGS

FIG. 1 is a schematic diagram of an overall structure of a piezoelectric linear motor in use according to an embodiment of the present disclosure;

FIG. 2 is a schematic diagram of an overall structure of a first possible implementation of a driving structure according to an embodiment of the present disclosure;

FIG. 3 is a schematic diagram of an overall structure of a second possible implementation of the driving structure according to an embodiment of the present disclosure;

FIG. 4 is a front view of a third possible implementation of the driving structure according to an embodiment of the present disclosure;

FIG. 5 is a schematic diagram of an overall structure of a fourth possible implementation of the driving structure according to an embodiment of the present disclosure;

FIG. 6 is a front view of a fifth possible implementation of the driving structure according to an embodiment of the present disclosure;

FIG. 7 is a schematic diagram of an overall structure of a sixth possible implementation of the driving structure according to an embodiment of the present disclosure;

FIG. 8 is a schematic diagram of an overall structure of a seventh possible implementation of the driving structure according to an embodiment of the present disclosure;

FIG. 9 is a schematic diagram of an overall structure of an eighth possible implementation of the driving structure according to an embodiment of the present disclosure;

FIG. 10 is a sectional view taken along a direction A-A in FIG. 9;

FIG. 11 is a schematic diagram of an overall structure of a ninth possible implementation of the driving structure according to an embodiment of the present disclosure;

FIG. 12 is a sectional view taken along a direction B-B in FIG. 11;

FIG. 13 is a schematic diagram of an overall structure of a tenth possible implementation of the driving structure according to an embodiment of the present disclosure;

FIG. 14 is a sectional view taken along a direction C-C in FIG. 13;

FIG. 15 is a front view of an eleventh possible implementation of the driving structure according to an embodiment of the present disclosure; and

FIG. 16 is a schematic diagram of superposition of two piezoelectric linear motors according to an embodiment of the present disclosure.

### DESCRIPTION OF EMBODIMENTS

The present disclosure is further described below with reference to the accompanying drawings and embodiments.

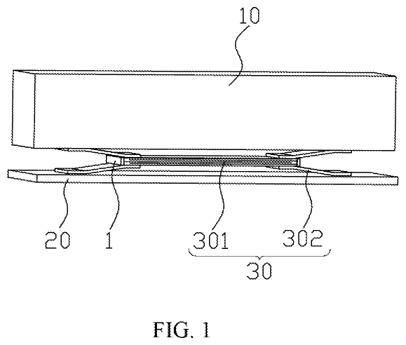

Referring to FIG. 1 to FIG. 16, an embodiment of the present disclosure provides an electronic device, including a first substrate 10, a second substrate 20, and at least one piezoelectric linear motor 30 connected to the first substrate 10 and the second substrate 20. The piezoelectric linear motor 30 is configured to drive the first substrate 10 and/or the second substrate 20 to move along a first direction (a direction perpendicular to a surface of the first substrate 10) when a voltage is applied. The electronic device may be a mobile phone, a tablet, a laptop computer, a stylus, a vehicle-mounted device, or the like. The first substrate 10 may be a component with mass such as a weight/battery/screen/pressing key. The second substrate 20 may be a base or another fixed component. The piezoelectric linear motor 30 is configured to drive the first substrate 10 and/or the second substrate 20 to move along the first direction when a voltage is applied, to generate haptic feedback. For example, the electronic device may be a mobile phone, the first substrate 10 may be a screen of the mobile phone, and the second substrate 20 may be a housing of the mobile phone. When a user touches the screen of the mobile phone, the piezoelectric linear motor 30 may drive the screen to move along the first direction to generate haptic feedback, thereby notifying, through the haptic feedback, the user that a touch operation is successfully implemented.

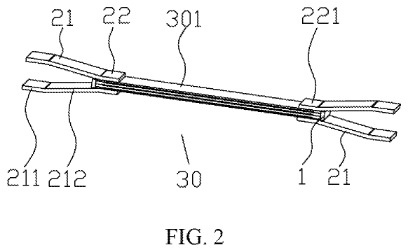

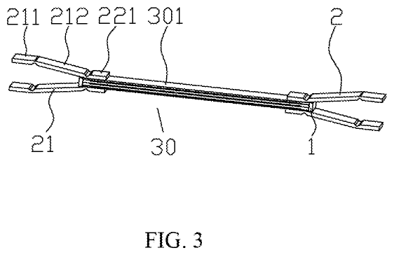

Some implementations of the piezoelectric linear motor 30 according to the present disclosure are described below. Referring to FIG. 2 and FIG. 3, the piezoelectric linear motor 30 includes a piezoelectric actuator 301 and an elastic structure 302 fixed to two opposite sides of the piezoelectric actuator 301 along a first direction. The first direction is perpendicular to a plane where a telescopic direction of the piezoelectric actuator 301 is located. The piezoelectric actuator 301 is configured to extend and retract and drive the elastic structure 302 to move in the first direction when a voltage is applied. The elastic structure 302 includes at least two sets of elastic connecting portions 2 fixed to end portions of the piezoelectric actuator 301 along the telescopic direction thereof. Each set of the at least two sets of elastic connecting portions 2 includes two connecting legs 21 respectively fixed to two opposite sides of the piezoelectric actuator 301 along the first direction. Each of the connecting legs 21 extends toward an outer side of the piezoelectric actuator 301, and the connecting legs 21 located on a same side of the piezoelectric actuator 301 in the first direction extend in directions away from each other. An angle θ is formed between each of the connecting legs 21 and a plane where the piezoelectric actuator 301 is located.

With the configuration described above, a small change in a length of the piezoelectric actuator in the telescopic direction is converted into a large displacement of the elastic structure 302 perpendicular to the telescopic direction of the piezoelectric actuator, thereby generating great haptic feedback intensity that is easily perceived. At the same time, it is conducive to reducing a thickness of the piezoelectric linear motor. In addition, the connecting legs 21 are independent from each other and thus have better flexibility, so that the elastic structure 302 has stronger deformation capability, which can improve a haptic feedback response speed of the electronic device.

It is to be noted that the piezoelectric actuator 301 generates extension or retraction along a direction of an extension surface thereof when a voltage is applied, so that the connecting leg 21 moves along the first direction relative to the piezoelectric actuator 301, and lateral telescopic displacement of the piezoelectric actuator 301 can be converted into up and down displacement of the elastic structure 302, thereby driving the second substrate 20 to move along the first direction to generate haptic feedback. For the convenience of subsequent description, the telescopic direction of the piezoelectric actuator 301 is defined as a direction X1, the first direction is defined as a direction X2, and the direction X2 is perpendicular to the direction X1.

Referring to FIG. 2, further, an angle θ formed between the connecting leg 21 and the plane where the piezoelectric actuator 301 is located is smaller than 45°. For example, the angle θ may be 15°, 20°, 30°, 40°, or the like. The angle θ is smaller than 45°, so that the connecting leg 21 can magnify displacement of the piezoelectric actuator 301 along the direction X1, thereby alleviating the problem of small response displacement or a large applied voltage of the piezoelectric actuator 301. A principle of a magnification function realized by the connecting leg 21 satisfies the following formula:

$$K = tan θ = \frac{Δ x 2}{Δ x 1} ;$$

where K denotes a magnification factor, Δx2 denotes displacement of the connecting leg 21 along the direction X2, and Δx1 denotes displacement of the piezoelectric actuator 301 along the direction X1. That is, the magnification factor is a ratio of the displacement of the piezoelectric actuator 301 to the displacement of the connecting leg 21, so that a length of the connecting leg 21 and a size of the angle θ can be changed to adjust the magnification factor.

Referring to FIG. 2 to FIG. 16, further, each set of elastic connecting portions 2 further includes a connecting assembly 22 fixed to the piezoelectric actuator 301, and the connecting leg 21 is fixed to the piezoelectric actuator 301 through the connecting assembly 22. Each connecting leg 21 includes a cantilever portion 212 fixed to the connecting assembly 22 and a first connecting portion 211 fixed to an end of the cantilever portion 212 away from the connecting assembly 22. An angle θ is formed between the cantilever portion 212 and the plane where the piezoelectric actuator 301 is located. For example, the two sets of elastic connecting portions 2 are respectively arranged at a left end and a right end of the piezoelectric actuator 301 along the telescopic direction X1, each set of elastic connecting portions 2 is formed by two connecting legs 21 and the connecting assembly 22, and the two connecting legs 21 of a same set of elastic connecting portions 2 are respectively arranged at upper and lower sides of the piezoelectric actuator 301 along the first direction X2, which is conducive to arranging the four connecting legs 21 to be independent from each other. The first connecting portion 211 located at the upper side of the piezoelectric actuator 301 is configured to be fixedly connected to the second substrate 20, and the first connecting portion 211 located at the lower side of the piezoelectric actuator is configured to be fixedly connected to the first substrate 10, to assemble the piezoelectric linear motor 30 in the electronic device.

Referring to FIG. 3, in a first possible implementation, the connecting assembly 22 includes at least first fixation portions 221 respectively connecting the cantilever portion 212 of each connecting leg 21 and the piezoelectric actuator 301, the first fixation portions 221 are in a shape of a flat plate, and the first fixation portions 221 connecting a same set of the elastic connecting portions 2 are fixed to surfaces of two opposite sides of the piezoelectric actuator 301 along the first direction. For example, the first fixation portion 221 and the piezoelectric actuator 301 may be fixed by epoxy glue, and the first connecting portion 211, the cantilever portion 212, and the first fixation portion 221 located on each of the upper and lower sides of the piezoelectric actuator 301 can be connected into one piece, i.e., a metal sheet. The metal sheet may be made of a material such as titanium, titanium alloy, or stainless steel. The metal sheet may be integrally formed by stamping, thereby reducing manufacturing difficulty and costs of the elastic structure 302. The two first fixation portions 221 of a same set of elastic connecting portions 2 are respectively arranged on two opposite surfaces of the piezoelectric actuator 301 along the first direction, to arrange the two connecting legs 21 of a same set of elastic connecting portions 2 on the upper and lower sides of the piezoelectric actuator 301, thereby facilitating fixing of the first substrate 10 and the second substrate 20 to the corresponding connecting legs 21.

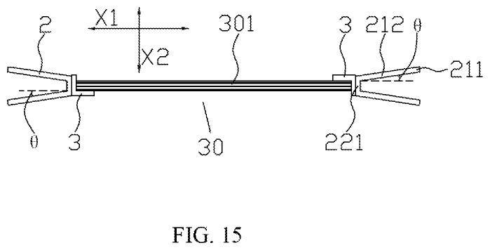

Referring to FIG. 2 and FIG. 15, according to an actual requirement, the cantilever portion 212 and the first fixation portion 221, and the first connecting portion 211 and the cantilever portion 212 are connected by bending or smooth transition. For example, the cantilever portion 212 and the first fixation portion 221, and the first connecting portion 211 and the cantilever portion 212 are connected by bending, so that the first connecting portion 211 can be arranged horizontally under a premise of ensuring the angle θ between the cantilever portion 212 and the plane where the piezoelectric actuator 301 is located, which is conducive to connections between the first connecting portion 211 and the first substrate 10 and between the first connecting portion 211 and the second substrate 20.

Referring to FIG. 3, in a second possible implementation, thicknesses of a junction between the cantilever portion 212 and the first fixation portion 221 and a junction between the first connecting portion 211 and the cantilever portion 212 are each smaller than a thickness of the cantilever portion 212. For example, the bending portion between the cantilever portion 212 and the first fixation portion 221 and the bending portion between the first connecting portion 211 and the cantilever portion 212 can be thinned. That is, part of material is removed from the bending portion, so that the thicknesses of the bending portion is smaller than the thickness of the cantilever portion 212. It should be understood that the bending portion of the metal sheet formed by connecting the first connecting portion 211, the cantilever portion 212 and the first fixation portion 221 is a deformable portion, and the thinning of the bending portion can reduce overall rigidity of the metal sheet.

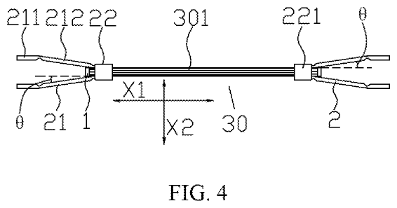

Referring to FIG. 4, in a third possible implementation, the first fixation portions 221 connecting the connecting legs 21 of a same set of the elastic connecting portions 2 are integrally connected. For example, the two first fixation portions 221 connecting a same set of the elastic connecting portions 2 are connected to form a sleeve, and the piezoelectric actuator 301 passes through the sleeve, so that the sleeve can provide pretension of the piezoelectric actuator 301 along the thickness direction, thereby improving reliability of the piezoelectric actuator 301. It should be understood that the two first fixation portions 221 of a same set of the elastic connecting portions 2 are integrally formed, so that the two connecting legs 21 located at the upper and lower sides of the piezoelectric actuator 301 and the connecting assembly 22 are formed into a single structure for machining, thereby simplifying a number of required parts and further improving reliability of the elastic connecting portion 2. At the same time, an assembly process can be simplified.

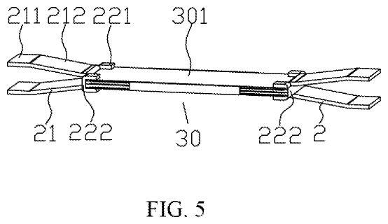

Referring to FIG. 5, in a fourth possible implementation, the connecting assembly 22 further includes a second fixation portion 222 fixed to an outer side wall of the piezoelectric actuator 301, and the first fixation portions 221 corresponding to the connecting legs 21 of a same set of the elastic connecting portions 2 are connected to each other through the second fixation portion 222. For example, the second fixation portion 222 can be arranged at an end portion of the piezoelectric actuator 301 along the telescopic direction thereof, and the first fixation portions 221 corresponding to the connecting legs 21 of a same set of the elastic connecting portions 2 are connected to each other through the second fixation portion 222 to form a U-shaped structure. That is, the connecting assembly 22 may be integrally formed, and in a same set of the elastic connecting portions 2, the connecting assembly 22, the connecting leg 21 at the upper side of the piezoelectric actuator 301, and the connecting leg 21 at the lower side of the piezoelectric actuator 301 may be integrally formed, so that the set of elastic connecting portions 2 can be integrally formed, thereby simplifying a machining and manufacturing process.

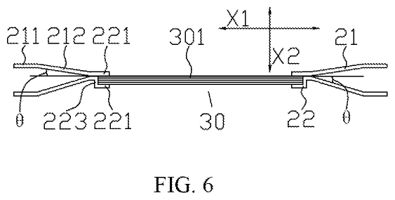

Referring to FIG. 6, in a fifth possible implementation, the connecting assembly 22 connecting a same set of the elastic connecting portions 2 further includes a third fixation portion 223 extending from one first fixation portion 221 along the first direction and fixed to an outer side wall of the piezoelectric actuator 301. The cantilever portion 212 of the connecting leg 21 located at a side of the piezoelectric actuator 301 along the first direction is fixed to the piezoelectric actuator 301 through the first fixation portion 221, and the cantilever portion 212 of the connecting leg 21 located at another side is connected to the third fixation portion 223. For example, the cantilever portion 212 located at the upper side of the piezoelectric actuator 301 is directly connected to the first fixation portion 221, and the cantilever portion 212 located at the lower side of the piezoelectric actuator 301 is connected to the first fixation portion 221 through the third fixation portion 223. The first fixation portion 221 located at the upper side of the piezoelectric actuator 301, the first fixation portion 221 located at the lower side of the piezoelectric actuator, and the third fixation portion 223 are jointly formed at the end portion of the piezoelectric actuator 301 along the telescopic direction, so that the connecting assembly 22 surrounds and fastened to the end portion of the piezoelectric actuator 301, thereby improving firmness and reliability of the connection compared with the connection by glue.

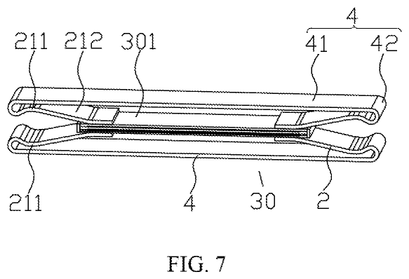

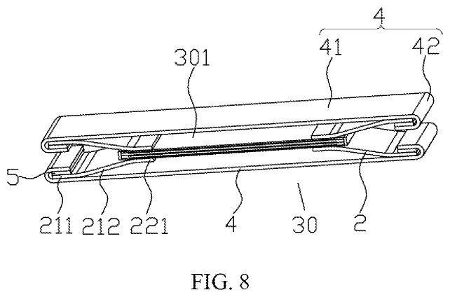

Referring to FIG. 7 and FIG. 8, further, the elastic structure 302 further includes a reinforcing member 4 connecting the connecting legs 21 located on a same side of the piezoelectric actuator 301 along the first direction, and the reinforcing member 4 is integrally formed with the connecting legs 21 at the same side of the piezoelectric actuator 301 or connected to the connecting legs 21 through a fixation member 5. For example, the reinforcing member 4 may be a reinforcing sheet, and the arrangement of the reinforcing member 4 can allow the piezoelectric linear motor 30 to be fixedly connected to another structure. Two ends of the reinforcing member 4 at the upper side of the piezoelectric actuator 301 are respectively fixed to two first connecting portions 211 at the upper side of the piezoelectric actuator 301 and belonging to different sets of elastic connecting portions 2, and two ends of the reinforcing member 4 at the lower side of the piezoelectric actuator 301 are respectively fixed to two first connecting portions 211 at the lower side of the piezoelectric actuator 301 and belonging to different sets of elastic connecting portions 2, so that the reinforcing member 4, the connecting legs 21, and the connecting assemblies 22 at the upper side of the piezoelectric actuator 301 form an integral structure, and the reinforcing member 4, the connecting legs 21, and the connecting assemblies 22 at the lower side of the piezoelectric actuator 301 form an integral structure, thereby reducing a number of parts. At the same time, lateral displacement can be constrained, and pre-stress required by the piezoelectric actuator 301 can also be directly provided, so that the piezoelectric actuator 301 can operate in a proper state.

Referring to FIG. 7, in a sixth possible implementation, the reinforcing member 4 includes a flat portion 41 parallel to the plane where the piezoelectric actuator 301 is located and a bending portion 42 extending from each of two ends of the flat portion 41 along a direction perpendicular to the first direction and connected to the first connecting portion 211, and the bending portion 42 is integrally formed with the first connecting portion 211. It should be understood that, in this case, two elastic connecting portions 2 in different sets and the reinforcing member 4 that are located at the upper side of the piezoelectric actuator 301 are integrally formed, and two elastic connecting portions 2 in different sets and the reinforcing member 4 that are located at the lower side of the piezoelectric actuator 301 are integrally formed, which is conducive to reducing the number of parts and constraining the lateral displacement.

Referring to FIG. 8, in a seventh possible implementation, the reinforcing member 4 includes a flat portion 41 parallel to the plane where the piezoelectric actuator 301 is located and a bending portion 42 extending from each of two ends of the flat portion 41 along a direction perpendicular to the first direction and connected to the first connecting portion 211, and the fixation member 5 is arranged between the bending portion 42 and the first connecting portion 211. For example, the fixation member 5 may be a fixation block, and the arrangement of the fixation member 5 enables a plate surface of the flat portion 41 and the first connecting portion 211 to fit each other, thereby preventing generation of a space that may produce vibration between the flat portion 41 and the first connecting portion 211.

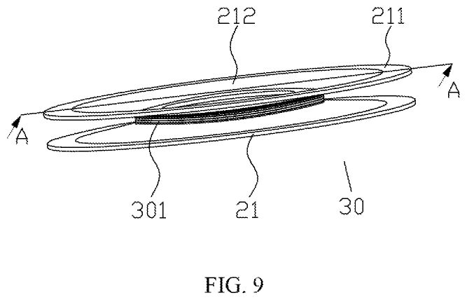

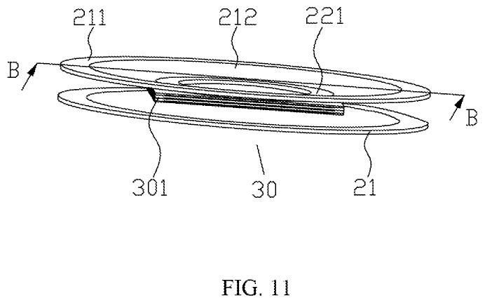

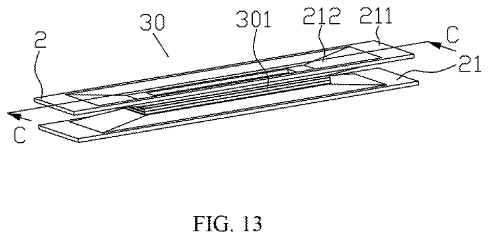

Referring to FIG. 9, FIG. 11, and FIG. 13, the connecting legs 21 located at a same side of the piezoelectric actuator 301 along the first direction are connected to each other to be formed into one piece, so that the elastic structure 302 fixed to the piezoelectric actuator 301 has a truncated cone shape as a whole.

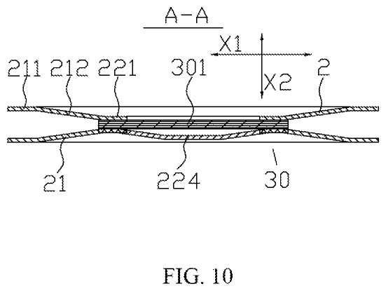

Referring to FIG. 9 and FIG. 10, in an eighth possible implementation, the connecting assembly 22 further includes a second connecting portion 224 connecting the first fixation portions 221 located at a same side of the piezoelectric actuator 301 along the first direction, and the second connecting portion 224 is spaced apart from the piezoelectric actuator 301 in the first direction. For example, the piezoelectric actuator 301 may be in a shape of a circle, and the elastic structure 302 may be in a shape of a cone with a certain height. For example, the first connecting portion 211, the cantilever portion 212, and the first fixation portion 221 located at each of the upper side and the lower side of the piezoelectric actuator 301 can be connected to form a tapered surface, and two first connecting portions 211 of the two elastic connecting portions 2 in different sets at the upper side of the piezoelectric actuator 301 are connected, and the two first fixation portions 221 are connected through the second connecting portion 224. The two first connecting portions 211 of the two elastic connecting portions 2 in different sets at the lower side of the piezoelectric actuator 301 are connected, and the two first fixation portions 221 are connected through the second connecting portion 224. In this way, a disc-shaped piezoelectric linear motor 30 is formed. The elastic connecting portion 2 is fixed to an end portion of the piezoelectric actuator 301 close to an outer edge, to make full use of mechanical deformation of the piezoelectric actuator 301. The piezoelectric actuator 301 is placed at apex of each of two cones. It should be understood that, when the disc-shaped piezoelectric linear motor 30 has a same piezoelectric actuator 301 and a same elastic structure 302 as a strip-shaped piezoelectric linear motor 30 (as shown in FIG. 1 to FIG. 8), an operation manner and a vibration effect of the disc-shaped piezoelectric linear motor 30 are consistent with those of the strip-shaped piezoelectric linear motor 30.

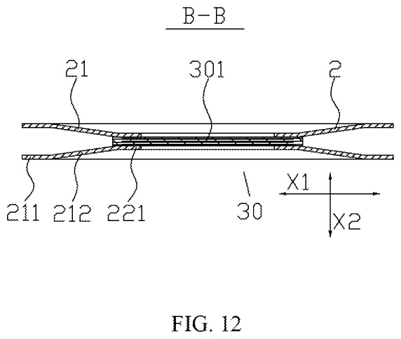

Referring to FIG. 11 and FIG. 12, in a ninth possible implementation, the piezoelectric actuator 301 may be in a shape of a square, and the elastic structure 302 may be in a shape of a cone with a certain height. For example, the first connecting portion 211, the cantilever portion 212, and the first fixation portion 221 located at each of the upper side and the lower side of the piezoelectric actuator 301 may be connected to form a tapered surface, the first connecting portions 211 of the elastic connecting portions 2 in different sets at the upper side of the piezoelectric actuator 301 are connected, the cantilever portions 212 are connected, the first fixation portions 221 are integrally connected, and the whole is in a shape of a truncated cone. The first connecting portions 211 of the elastic connecting portions 2 in different sets at the lower side of the piezoelectric actuator 301 are connected, the cantilever portions 212 are connected, the first fixation portions 221 are integrally connected, and the whole is in a shape of a truncated cone. In this way, a disc-shaped piezoelectric linear motor 30 is formed. The elastic connecting portion 2 is fixed to an end portion of the piezoelectric actuator 301 close to an outer edge, to make full use of mechanical deformation of the piezoelectric actuator 301. The piezoelectric actuator 301 is placed at apex of each of the two cones. It should be understood that, when the disc-shaped piezoelectric linear motor 30 has a same piezoelectric actuator 301 and a same elastic structure 302 as a strip-shaped piezoelectric linear motor 30 (as shown in FIG. 1 to FIG. 8), an operation manner and a vibration effect of the disc-shaped piezoelectric linear motor 30 are consistent with those of the strip-shaped piezoelectric linear motor 30.

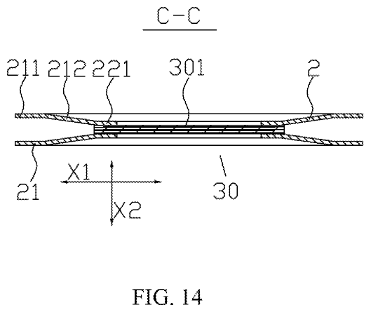

Referring to FIG. 13 and FIG. 14, in a tenth possible implementation, each of the piezoelectric actuator 301 and the elastic structure 302 may be in a shape of a square. For example, the first connecting portions 211 of the elastic connecting portions 2 in different sets at the upper side of the piezoelectric actuator 301 are connected, the cantilever portions 212 are connected, the first fixation portions 221 are integrally connected, and the whole is in a shape of a truncated cone. The first connecting portions 211 of the elastic connecting portions 2 in different sets at the lower side of the piezoelectric actuator 301 are connected, the cantilever portions 212 are connected, the first fixation portions 221 are integrally connected, and the whole is in a shape of a truncated cone. In this way, a square-shaped piezoelectric linear motor 30 is formed. It should be understood that, when the square-shaped piezoelectric linear motor 30 has a same piezoelectric actuator 301 and a same elastic structure 302 as a strip-shaped piezoelectric linear motor 30 (as shown in FIG. 1 to FIG. 8), an operation manner and a vibration effect of the square-shaped piezoelectric linear motor 30 are consistent with those of the strip-shaped piezoelectric linear motor 30.

Referring to FIG. 15, in an eleventh possible implementation, the piezoelectric linear motor 30 further includes two pressing members 3 fixed to the piezoelectric actuator 301 and distributed at two opposites sides of the piezoelectric actuator 301 along the telescopic direction X1, the connecting assembly 22 connects the first fixation portion 221 corresponding to the cantilever portion 212, and the two pressing members 3 are capable of jointly forming a pre-tightening force that compresses the piezoelectric actuator 301 along the telescopic direction of the piezoelectric actuator 301. For example, each of the two pressing members 3 may be an L-shaped block, the L-shaped block located at a left end of the piezoelectric actuator 301 is arranged upright, and the L-shaped block located at a right end of the piezoelectric actuator 301 is arranged upside down, so that, by compressing the elastic structure 302, the two pressing members 3 located at the left and right ends of the piezoelectric actuator 301 can provide a piezoelectric layer in the piezoelectric actuator 301 with a pre-tightening force for left and right compression. Moreover, the piezoelectric layer is made of a piezoelectric material, which improves reliability and a voltage operation range of the piezoelectric material. The piezoelectric layer has characteristics of compression resistance and non-tensile resistance, and has an operation voltage range with certain breakdown field strength.

It is to be noted that the piezoelectric actuator 301 includes: a sintered component formed by stacking a plurality of piezoelectric layers and a plurality of internal electrodes, and two external electrodes 1 fixed to two ends of the sintered component. The piezoelectric layer is generally made of single-layer or multi-layer lead zirconate titanate ceramics (PZT ceramics), and internal electrodes of different polarities are alternately arranged and electrically connected to the corresponding external electrodes 1. When a voltage is applied to the two external electrodes 1, an electric field along a polarization direction can be generated, and due to an inverse piezoelectric effect, the piezoelectric actuator 301 is deformed to extend and retract along the direction X1.

In an embodiment, the piezoelectric actuator 301 extends and retracts along the thickness direction and has a telescopic distance of less than or equal to 10 mm, and extends and retracts along a length direction and has a telescopic distance of less than or equal to 100 mm. The thickness of the piezoelectric actuator 301 can be properly optimized according to an application scenario and a number of layers of the PZT ceramics. When a voltage is applied to the external electrode, the piezoelectric actuator 301 deforms and extends and retracts along the direction X1 (perpendicular to a direction of an electric field of the internal electrode, due to an inverse piezoelectric effect in a direction d31). According to an actual requirement, the piezoelectric actuator 301 polarized along the thickness direction of the multi-layer PZT ceramics may alternatively be adopted (the telescopic direction of the piezoelectric actuator 301 is in a same dimension as a direction of an applied electric field, due to an inverse piezoelectric effect in a direction d33). In this case, a pre-tightening force is required to be added to the piezoelectric layer to prevent failure of the piezoelectric actuator 301.

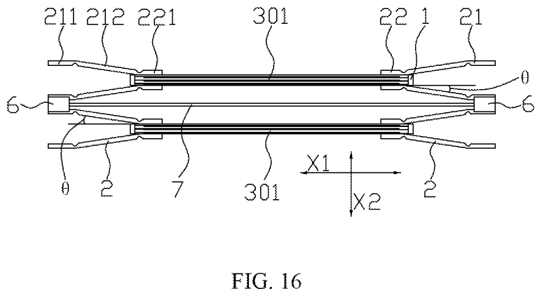

Referring to FIG. 16, in an embodiment, the electronic device may be provided with a plurality of piezoelectric linear motors 30, and the plurality of piezoelectric linear motors 30 are superposed to improve strength of the piezoelectric linear motors to generate greater haptic feedback intensity. When two piezoelectric linear motors 30 are superposed, displacement of the piezoelectric actuator 301 can be magnified to the greatest extent, and an overall magnification factor is a sum of magnification factors of the two. In this case, there is a need to add a connection structure that connects two ends and limits lateral motion. For example, in FIG. 16, two connecting blocks 6 and a connecting rod 7 connected to the two connecting blocks 6 are provided, to convert lateral motion into up and down motion.

The above descriptions are only embodiments of the present disclosure. It should be noted that, for those of ordinary skill in the art, improvements can also be made without departing from the creative concept of the present disclosure, all of which shall fall within a scope of the present disclosure.

What is claimed is:

1. A piezoelectric linear motor, comprising:
a piezoelectric actuator; and
an elastic structure fixed to two opposite sides of the piezoelectric actuator along a first direction, the first direction being perpendicular to a plane where a telescopic direction of the piezoelectric actuator is located,
wherein the piezoelectric actuator is configured to extend and retract to drive the elastic structure to move in the first direction when a voltage is applied,
wherein the elastic structure comprises at least two sets of elastic connecting portions fixed to end portions of the piezoelectric actuator along the telescopic direction, each set of the at least two sets of elastic connecting portions comprises two connecting legs respectively fixed to two opposite sides of the piezoelectric actuator along the first direction, each of the connecting legs extends toward an outer side of the piezoelectric actuator, and the connecting legs located at a same side of the piezoelectric actuator along the first direction extend in a direction away from each other, and an angle is formed between each of the connecting legs and a plane where the piezoelectric actuator is located.

2. The piezoelectric linear motor as described in claim 1, wherein the angle formed between the connecting leg and the plane where the piezoelectric actuator is located is smaller than 45°.

3. The piezoelectric linear motor as described in claim 1, wherein each set of the at least two sets of elastic connecting portions further comprises a connecting assembly fixed to the piezoelectric actuator, and each of the connecting legs is fixed to the piezoelectric actuator through the connecting assembly; wherein each of the connecting legs comprises a cantilever portion fixed to the connecting assembly and a first connecting portion fixed to an end of the cantilever portion away from the connecting assembly, and the angle is formed between the cantilever portion and the plane where the piezoelectric actuator is located.

4. The piezoelectric linear motor as described in claim 3, wherein the connecting assembly at least comprises a first fixation portions respectively connecting the cantilever portion of each of the connecting legs and the piezoelectric actuator, the first fixation portion is in a shape of a flat plate, the first fixation portions connecting a same set of the at least two sets of elastic connecting portions are fixed to two opposite surfaces of the piezoelectric actuator along the first direction, respectively.

5. The piezoelectric linear motor as described in claim 4, wherein the cantilever portion and the first fixation portion, and the first connecting portion and the cantilever portion are connected by bending or smooth transition.

6. The piezoelectric linear motor as described in claim 4, wherein a thicknesses of a junction between the cantilever portion and the first fixation portion is smaller than a thickness of the cantilever portion, and a thickness of a junction between the first connecting portion and the cantilever portion is smaller than the thickness of the cantilever portion.

7. The piezoelectric linear motor as described in claim 4,
wherein the first fixation portions connecting the connecting legs of a same set of the elastic connecting portions are formed into one piece; or
wherein the connecting assembly further comprises a second fixation portion fixed to an outer side wall of the piezoelectric actuator, and the first fixation portions connecting the connecting legs of a same set of the elastic connecting portions are connected to each other through the second fixation portion.

8. The piezoelectric linear motor as described in claim 4, wherein the connecting assembly connecting a same set of the elastic connecting portions further comprises a third fixation portion extending from one of the first fixation portions along the first direction and fixed to an outer side wall of the piezoelectric actuator, and the cantilever portions of the connecting legs located at a side of the piezoelectric actuator along the first direction are each fixed to the piezoelectric actuator through the first fixation portion; and the cantilever portions of the connecting legs located at another side of the piezoelectric actuator along the first direction are each connected to the third fixation portion.

9. The piezoelectric linear motor as described in claim 4, wherein the connecting legs located at a same side of the piezoelectric actuator along the first direction are formed into one piece.

10. The piezoelectric linear motor as described in claim 9, wherein the connecting assembly further comprises a second connecting portion connecting the first fixation portions located on a same side of the piezoelectric actuator along the first direction, the second connecting portion being arranged apart from the piezoelectric actuator along the first direction.

11. The piezoelectric linear motor as described in claim 3, wherein the piezoelectric linear motor further comprises two pressing members fixed to the piezoelectric actuator and located at two opposites sides of the piezoelectric actuator along the telescopic direction, the connecting assembly is configured to connect each of the two pressing members and the cantilever portion, and the two pressing members jointly form a pre-tightening force that compresses the piezoelectric actuator along the telescopic direction of the piezoelectric actuator.

12. The piezoelectric linear motor as described in claim 4, wherein the elastic structure further comprises a reinforcing member connecting the connecting legs located at a same side of the piezoelectric actuator along the first direction, the reinforcing member and the connecting legs located at the same side of the piezoelectric actuator are formed into one piece, or the reinforcing member is connected to each of the connecting legs located at the same side of the piezoelectric actuator through a fixation member.

13. The piezoelectric linear motor as described in claim 12, wherein the reinforcing member comprises a flat portion parallel to the plane where the piezoelectric actuator is located, and a bending portion extending from each of two ends of flat portion in a direction perpendicular to the first direction and connected to the first connecting portion, and the fixation member is arranged between the bending portion and the first connecting portion or the bending portion and the first connecting portion are formed into one piece.

14. An electronic device, comprising a first substrate, a second substrate, and at least one piezoelectric linear connected to the first substrate and the second substrate, wherein each of the at least one piezoelectric linear motor comprises:
a piezoelectric actuator; and
an elastic structure fixed to two opposite sides of the piezoelectric actuator along a first direction, the first direction being perpendicular to a plane where a telescopic direction of the piezoelectric actuator is located,
wherein the piezoelectric actuator is configured to extend and retract to drive the elastic structure to move in the first direction when a voltage is applied,
wherein the elastic structure comprises at least two sets of elastic connecting portions fixed to end portions of the piezoelectric actuator along the telescopic direction, each set of the at least two sets of elastic connecting portions comprises two connecting legs respectively fixed to two opposite sides of the piezoelectric actuator along the first direction, each of the connecting legs extends toward an outer side of the piezoelectric actuator, and the connecting legs located at a same side of the piezoelectric actuator along the first direction extend in a direction away from each other, and an angle is formed between each of the connecting legs and a plane where the piezoelectric actuator is located, and
wherein the piezoelectric linear motor is configured to drive at least tone of the first substrate or the second substrate to move along the first direction when a voltage is applied.
